(19) United States
(12) Patent Application Publication
(10) Pub. No.: US 2012/0243180 A1
(43) Pub. Date: Sep. 27, 2012

(54) ENHANCED HEAT SINK

(75) Inventors: Poh Seng Lee, Singapore (SG); Yong Jiun Lee, Singapore (SG)

(73) Assignee: NATIONAL UNIVERSITY OF SINGAPORE, Singapore (SG)

(21) Appl. No.: 13/513,861

(22) PCT Filed: Apr. 29, 2010
(86) PCT No.: PCT/SG2010/000169

§ 371 Date: Jun. 4, 2012

Related U.S. Application Data
(60) Provisional application No. 61/265,825, filed on Dec. 2, 2009.

(51) Int. Cl. H05K 7/20

(52) U.S. Cl. 361/702

(57) ABSTRACT

A heat sink device for dissipating heat from an electronic component mounted thereto, the device comprising: an inlet for receiving a fluid; an outlet for venting said fluid; a heat dissipation zone intermediate the inlet and outlet; said zone including a plurality of transverse channels and a plurality of oblique channels extending between adjacent transverse channels; wherein said oblique and transverse channels define a fluid path for said fluid from the inlet to the outlet.

### FIELD OF THE INVENTION

The present invention relates to a heat sink, in particularly a heat sink for receiving a fluid to remove heat from an integrated circuit chip.

### BACKGROUND OF THE INVENTION

The ever-increasing density, speed, and power consumption of microelectronics has led to a rapid increase in the heat fluxes which need to be dissipated in order to ensure their stable and reliable operation. The shrinking dimensions of electronics devices, in parallel, have imposed severe space constraints on the volume available for the cooling solution, defining the need for innovative and highly effective compact cooling techniques.

U.S. Pat. No. 4,450,472 patent document disclosed a conventional microchannel heat sink having an array of microchannels separated by fins. The arrays of fins are disposed in an enclosure with a cover. The cover has an inlet aperture and outlet aperture. The inlet and outlet apertures are configured to receive a coolant from a pressurized coolant supply. The problem with the conventional microchannel heat sink is that significant temperature variations across the chip persist since the heat transfer performance deteriorates in the flow direction in microchannels as the boundary layers thicken and the coolant heats up. These temperature gradients across the chip can compromise the reliability of integrated circuits and result in early failures.

It is therefore highly desirable to further enhance the heat transfer performance of a microchannel heat sink.

### SUMMARY OF THE INVENTION

In a first aspect, the invention provides a heat sink device for dissipating heat from an electronic component mounted thereto, the device comprising: an inlet for receiving a fluid; an outlet for venting said fluid; a heat dissipation zone intermediate the inlet and outlet; said zone including a plurality of transverse channels and a plurality of oblique channels extending between adjacent transverse channels; wherein said oblique and transverse channels define a fluid path for said fluid from the inlet to the outlet.

In one embodiment, the invention may provide an enhanced micro- and mini-channel heat sink comprising at least one transverse channel with the introduction of at least one oblique channel in a surface of the heat sink. The transverse channel may be elongate and extending in a direction parallel to an axis of the heat sink, and the oblique channel may be arranged in a direction oblique to the axis.

The arrangement between the transverse and oblique branching channels may be such that the transverse channel is in fluid communication with the oblique branching channel.

According to the present invention, the thermal boundary layers of the heat sink device are periodically restarted at the leading edge of each interrupted oblique branching channel and, since the average boundary-layer thickness is thinner for short channels than for long channels, both the local and average heat transfer coefficient is higher for an interrupted surface than for a continuous surface.

The presence of the oblique branching channel also causes part of the fluid to be diverted from transverse channel into oblique branching channel and subsequently being injected into the adjacent transverse channel. The resulting secondary flow improves the fluid mixing and further enhances the heat transfer performance.

Further advantageous features of present invention are disclosed in the dependent claims.

### BRIEF DESCRIPTION OF THE DRAWINGS

It will be convenient to further describe the present invention with respect to the accompanying drawings that illustrate possible arrangements of the invention. Other arrangements of the invention are possible and consequently, the particularity of the accompanying drawings is not to be understood as superseding the generality of the preceding description of the invention.

FIG. 1(a) is an isometric view of the microchannel heat sink with oblique channels according to present invention.

FIG. 1(b) is a plan view of the microchannel heat sink of FIG. 1(a) showing the fluid flow pattern.

FIG. 2 shows a computational domain of the microchannel heat sink with oblique channels.

FIG. 3 shows bottom wall temperature profile for microchannel heat sink with oblique channels according to the embodiment of FIG. 1(a).

FIG. 4 shows local heat transfer coefficient for microchannel heat sink with oblique channels according to the invention of FIG. 1(a).

FIG. 5 shows pressure drop profile for microchannel heat sink with oblique channels according to the invention of FIG. 1(a).

FIG. 6(a) is an isometric view of the enhanced microchannel heat sink with denser oblique channels array.

FIG. 6(b) is a plan view of the microchannel heat sink of FIG. 6(a) showing the fluid flow pattern.

FIG. 7 shows bottom wall temperature profile for microchannel heat sink with oblique channels according to the invention of FIG. 6.

FIG. 8 shows local heat transfer coefficients profile for microchannel heat sink with oblique channels according to the invention of FIG. 6.

FIG. 9 shows average heat transfer coefficient profile for microchannel heat sinks set #1 (500 μm channel width).

FIG. 10 shows comparison of total thermal resistance of microchannel heat sinks in set #1 (500 μm channel width).

FIG. 11 shows average heat transfer coefficient profile for microchannel heat sinks set #2 (300 μm channel width).

FIG. 12 shows average heat transfer coefficient for microchannel heat sinks for set #3 (˜120 μm channel width).

FIG. 13 shows pressure drop profile for microchannel heat sinks set #3 (˜120 μm channel width).

FIG. 14(a) is an isometric view of the enhanced microchannel heat sink with non-uniform oblique channel pitch.

FIG. 14(b) is a plan view of the microchannel heat sink of FIG. 14(a) showing the fluid flow pattern.

FIG. 15 shows bottom wall temperature profile for microchannel heat sinks simulated with hotspot.

FIG. 16 shows total thermal resistance and pressure drop across the heat sink both as a function of angle of oblique cut.

FIG. 17 shows a plane view of a heat sink according to a further embodiment with non uniform fin pitch for multiple hot spots.

FIG. 18 shows an isometric view of the heat sink according to FIG. 17.

### DETAILED DESCRIPTION OF THE INVENTION

The present invention provides an enhanced micro-channel or mini-channel heat sink for receiving a fluid to remove heat from an integrated circuit chip. The embodiments discussed below are intended not to be exhaustive or limit the invention. It will be appreciated that whilst the examples provided in the various embodiments relate to channel dimensions of less than 1 mm, it will be appreciated that channel dimensions up to and in excess of 1 mm may equally fall within the scope of the present invention. Given the dimensions, development of turbulent flow in those channels having a maximum dimension of less than 1 mm may be difficult for practical levels of fluid flow. To this end, fluid flow may be laminar (Re<2300). This is not to preclude the possibility of turbulent flow (Re>2300) being established under certain conditions. Whilst the flow regime within the channels is not a limitation on the invention, practical applications of the invention may yield laminar flow more readily than turbulent flow.

The method of manufacture of a heat sink device according to the present invention may vary according to known practices for small scale devices. A non-exhaustive list of such methods includes, but not limited to, micro-machining, injection molding, wire-cut, liquid forging, diffusion bonding, stereo lithography, chemical etching and LIGA.

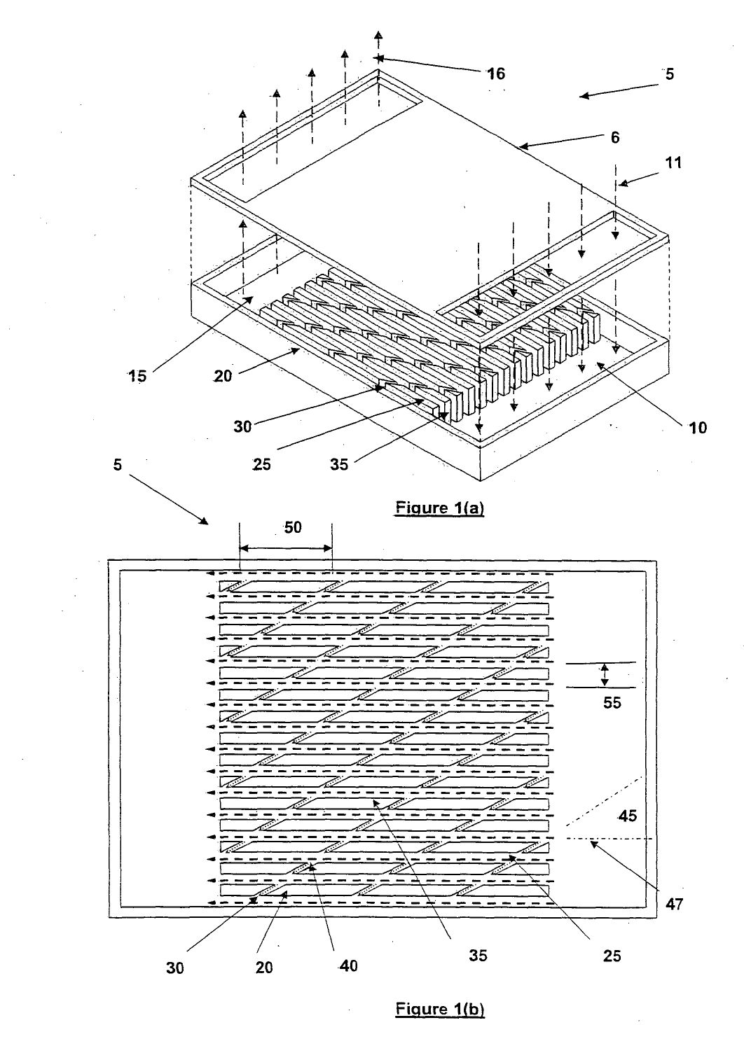

Referring to FIGS. 1(a) & 1(b), one embodiment of the enhanced microchannel heat sink 5 comprises at least one transverse channel 25 with the introduction of at least one oblique channel 30 in a surface of the heat sink. The heat sink device 5 according to the present invention, and as shown in the embodiments of FIGS. 1(a) and (b), comprise an inlet 11 into which a fluid 11 flows. Projecting from the inlet 10 is a plurality of transverse channels 25, which terminate at the outlet 15 from which the fluid 16 is vented.

Located between the transverse channels 25 are a plurality of oblique channels 30, which allow fluid communication between adjacent transverse channels.

The transverse and oblique channels define a fluid path from the inlet to the outlet. Accordingly, the transverse and oblique channels form a heat dissipation zone between the inlet and outlet. Subject to the design of individual heat sink devices, the heat dissipation zone may include the entire area between the inlet and outlet, or a smaller subset within the device.

It will be appreciated that the fluid may be a liquid, such as water, or a gas such as air. The precise nature of the fluid is separate from the invention, and may be applicable to a range of such heat dissipation fluids.

Whilst this embodiment shows a uniformly spaced 50, 55 array of transverse and oblique channels, the invention may include a variety of non-uniform transverse and/or oblique channels. Further, whilst the embodiment shows the transverse channels 25 parallel to the axis 47 of the heat sink device, other embodiments may include transverse channels at an angle to the axis, or even a curvi-linear path. This, the invention provides the designer of the heat sink device to control a number of parameters and so custom arrange the heat sink device to suit a variety of heat dissipation applications.

It will be noted that the transverse channel 25 is elongate and extending in a direction transverse to an axis 47 of the heat sink device 5, and the oblique channel is arranged at an angle, or oblique, to the transverse channel, and in this embodiment at an angle to the axis of the heat sink device. The arrangement between the transverse and oblique branching channels is such that the transverse channel is in fluid communication with the oblique channel. In one instance, the angle of the oblique channel is in the range between 15° to 45°.

In a further embodiment, the size of oblique channel may be smaller than the size of the transverse channel. In yet another embodiment, the microchannel heat sink may include an enclosure for housing the array of oblique channels. A cover 6 having an inlet aperture and outlet aperture may be arranged to secure to the enclosure. The inlet 10 and outlet 15 may be configured to receive a fluid 11, 15 from a pressurized fluid supply.

The thermal boundary layers for the present invention are periodically restarted at the leading edge of each interrupted oblique channel and, since the average boundary-layer thickness is thinner for short channels than for long channels, both the local and average heat transfer coefficient is higher for an interrupted surface than for a continuous surface. The presence of the oblique channel also causes part of the fluid 40 to be diverted from the transverse channel into the oblique channel and subsequently being injected into the adjacent transverse channel. This resulting secondary flow 40 may improve the fluid mixing and further enhance the heat transfer performance. The oblique channels are also sized such that the bulk of the fluid will flow through the transverse channels with a small fraction of flow is being induced into the oblique channels. The fluid path, which is divided into the main and secondary flows, is indicated in the plan view of the enhanced microchannel heat sink in FIG. 1(b).

CFD analyses show that for a given fixed mass flow rate, the proposed scheme leads to higher heat transfer rate with the negligible increment of pressure head. Both the maximum wall temperature and its temperature gradient are decreased dramatically as a result. In addition, convective heat transfer is significantly enhanced. Experimental investigation using both silicon thermal test dies and copper blocks also confirmed the enhanced heat transfer performance achieved in CFD analysis.

### Microchannel Liquid Cooling

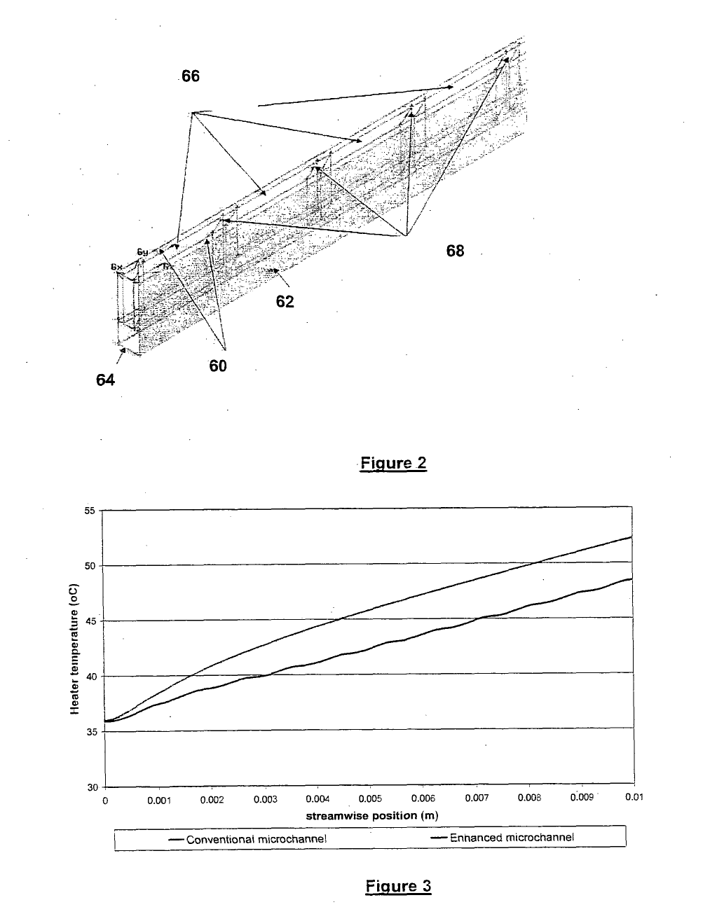

By way of an example the laminar flow and heat transfer in one embodiment of the microchannel heat sink device was investigated. The simulation is performed for the microchannel 60 as depicted in FIG. 2. The detailed geometric parameters are listed in Table 1. The coolant, water in this case, flows through the silicon microchannels with a mean velocity of 1 m/s and Reynolds number of 160. A uniform heat flux 64 of 100 W/cm² is supplied to the bottom wall of the heat sink. Due to periodic boundary condition 62, only a channel-fin 60, 66, 68 pair was modeled with the simulation domain illustrated in FIG. 2.

TABLE 1
Geometric parameters of the enhanced microchannel heat sink.

| Aspect | Fin | Channel | Channel | Fin | Fin | Substrate | Heat |
|---|---|---|---|---|---|---|---|
| ratio | width W_{w} | width W_{c} | height H | length L | pitch p | thickness t | flux q″ |
| α | (μm) | (μm) | (μm) | (μm) | (μm) | (μm) | (W/cm²) |
| 4 | 100 | 100 | 400 | 770 | 900 | 200 | 100 |

FIG. 3 shows the bottom wall (heater) temperature profile for the enhanced microchannel heat sink. The maximum wall temperature is T_{w,max}=48.4° C., while the temperature gradient is, ΔT_{wall}=12.6° C. The conventional microchannel heat sink on the other hand has a maximum wall temperature of 52.2° C. and a temperature gradient of maximum 16.3° C. Thus the introduction of oblique cuts along the fins resulted in the significant decrease of both the maximum wall temperature and temperature gradient of 3.8 and 3.7° C. respectively.

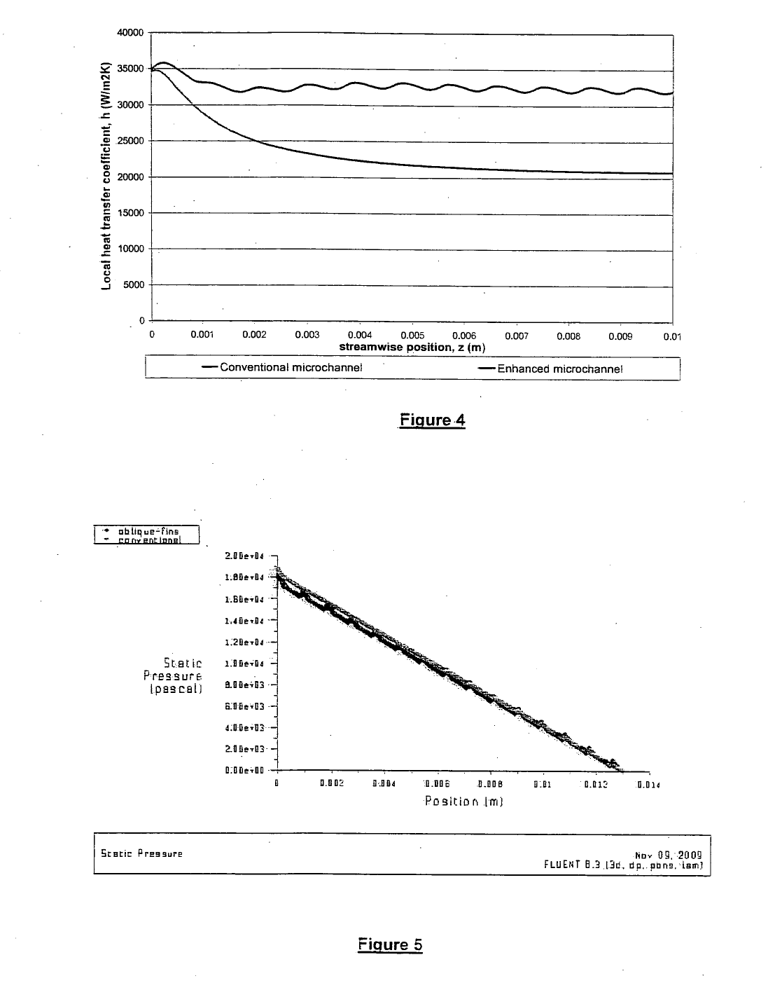

The introduction of the oblique channels leads to significant local and global heat transfer enhancement as illustrated in FIG. 4. The apparent local heat transfer coefficient is increased by 40% almost everywhere.

This heat transfer enhancement technique is particularly attractive as there may be little or no pressure drop penalty. It can be seen from FIG. 5 that the pressure drop for the enhanced microchannel heat sink can be comparable to that of a conventional microchannel heat sink.

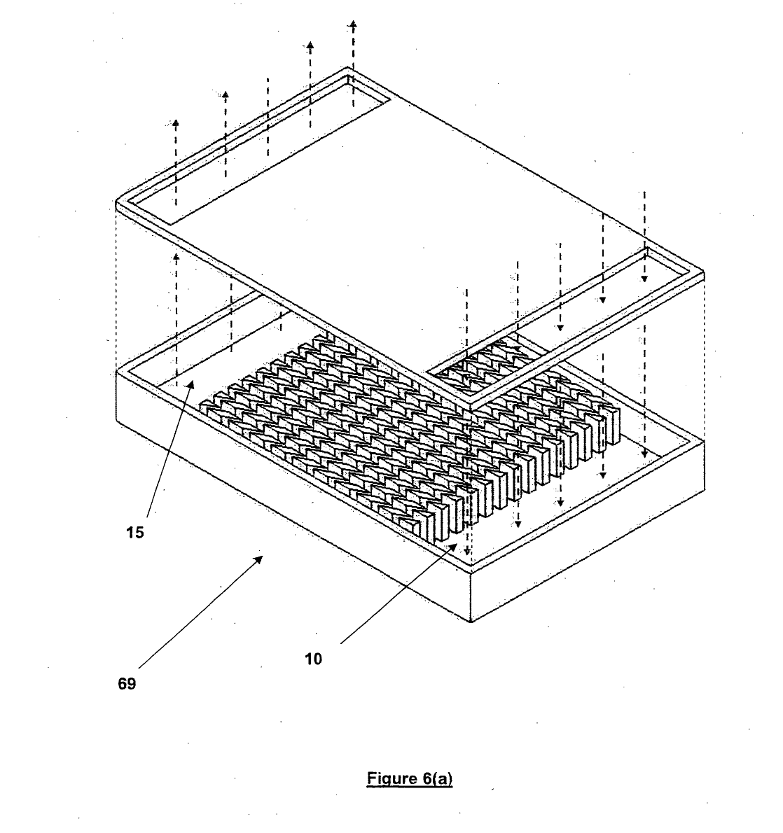

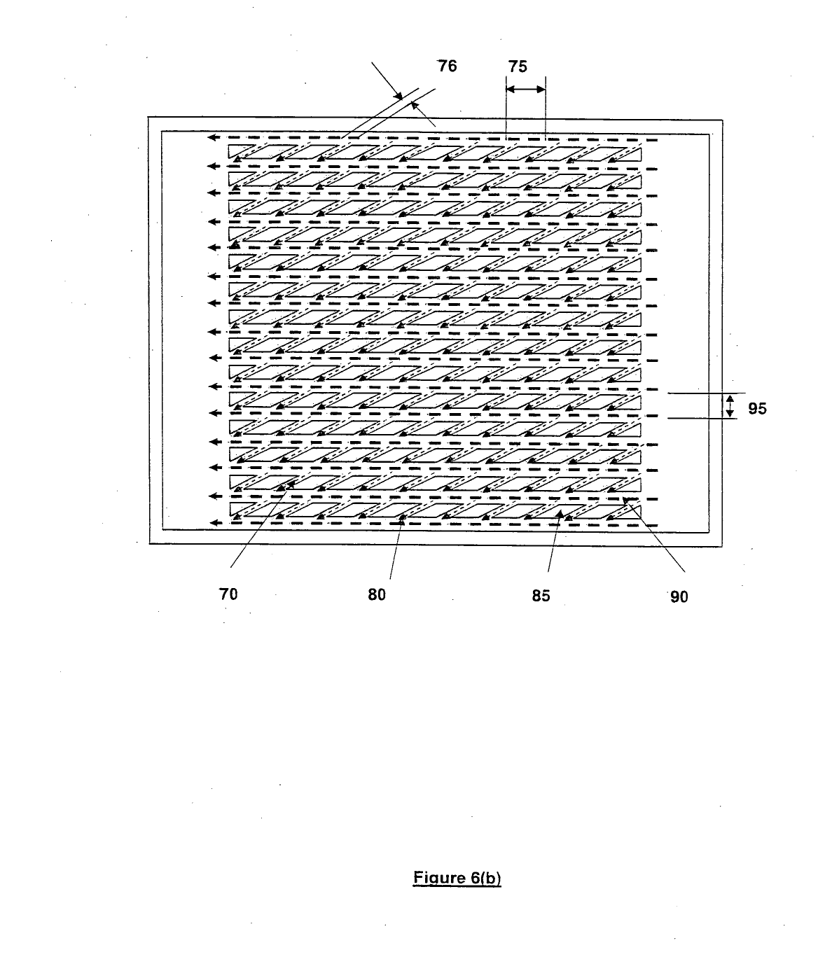

The pitch or spacing of the oblique channels can be varied to create an array of oblique channels at different density. For one embodiment, a denser array of oblique channels leads to higher occurrence of thermal boundary layer redevelopment and flow diversion, which can be translated to better heat transfer performance. Besides, changing other key parameters of the oblique channels such as the width of channels and the angle of the oblique channels would result in different pressure drop and heat transfer performance (especially for higher flow rate condition). Thus, optimization could be carried out to achieve significantly enhanced heat transfer performance at affordable pressure drop. FIGS. 6(a) & 6(b) illustrate the other configuration of enhanced microchannel 69, where the pitch 75 and width 76 for the oblique channels 70 are reduced, as compared to the spacing 95 of the transverse channel 90, resulting in a denser array of oblique channels 70, and smaller heat dissipating fins 85 about which the secondary flow 80 moves.

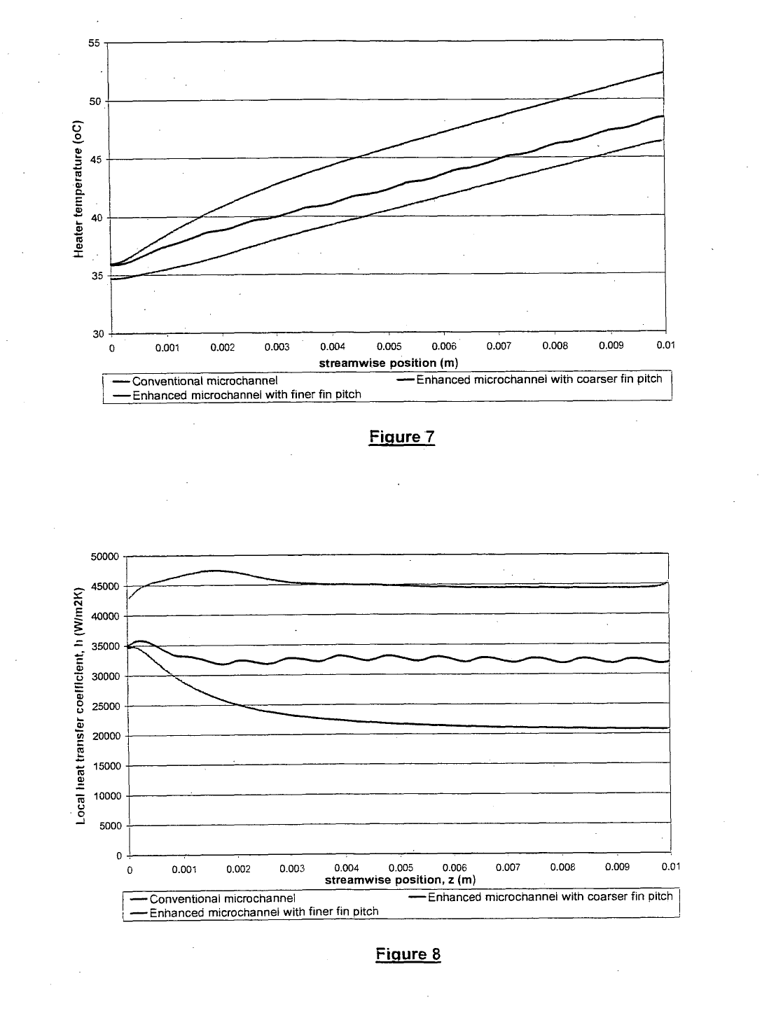

Simulation is also performed for the microchannel as depicted in FIG. 7 with the detailed geometric parameters listed in Table 2. The coolant/working fluid, water in this case, flows through the silicon microchannels with a mean velocity of 1 m/s and Reynolds number of 160. A uniform heat flux of 100 W/cm² is supplied to the bottom wall of the heat sink. Due to periodic boundary condition, only a channel-fin pair was modeled.

TABLE 2
Geometric parameters of the enhanced microchannel
heat sink with oblique cuts (smaller fin pitch).

| Aspect | Fin | Channel | Channel | Fin | Fin | Substrate | Heat |
|---|---|---|---|---|---|---|---|
| ratio | width W_{w} | width W_{c} | height H | length L | pitch p | thickness t | flux q″ |
| α | (μm) | (μm) | (μm) | (μm) | (μm) | (μm) | (W/cm²) |
| 4 | 100 | 100 | 400 | 200 | 300 | 200 | 100 |

The bottom wall (heater) temperature profiles for the conventional and enhanced microchannel heat sink are plotted in FIG. 7. The maximum wall temperature, T_{w,max} for the enhanced microchannel with smaller fin pitch is recorded at 46.4° C., while the temperature gradient is, ΔT_{wall}=11.6° C. This configuration showed further heat transfer enhancement, where both maximum wall temperature and temperature gradient is further lowered by 2.0° C. and 1.0° C. respectively in comparison with the enhanced microchannel with larger fin pitch.

Significant enhancement in local and global heat transfer coefficient is observed for the enhanced microchannel with finer fin pitch in comparison with conventional microchannel and enhanced microchannel with coarser fin pitch as demonstrated in FIG. 8. With finer fin pitch, the enhanced microchannel could achieve an average heat transfer coefficient of 45,000 W/m²K, which is ˜40% higher than the enhanced microchannel with coarser fin pitch and ˜80% higher compared with conventional microchannel.

Besides simulation, experimental investigation is also carried out to study both the pressure drop and heat transfer performance of the enhanced microchannels. Microchannel heat sinks made of copper (copper blocks) and silicon (flip chip thermal test dies) are both evaluated in the experiment. Copper based microchannel heat sinks are used in the performance evaluation for larger size channel while silicon based microchannel heat sink focus on smaller size channel. Detailed dimensions for each test piece are tabulated in Table 3. For each of the experimental set, there would be an enhanced microchannel with oblique cuts test piece and a corresponding conventional microchannel test piece with the similar/comparable dimensions.

TABLE 3
Dimensional details for microchannel heat sink test pieces

| | Set #1 | Set #2 | Set #3 |
|---|---|---|---|
| Material | Copper | Copper | Silicon |
| Footprint (mm) | 25 × 25 | 25 × 25 | 12.7 × 12.7 |
| Main channel width (μm) | 500 | 300 | 117 |
| Oblique channel width (μm) | 250 | 150 | 51 |
| Fin width (μm) | 500 | 300 | 83 |
| Fin pitch (μm) | 2000 | 1200 | 400 |
| Channel depth (μm) | 1500 | 1200 | 374 |
| Oblique angel (°) | ~27 | ~27 | ~27 |
| Number of channel | 23 | 40 | 62 |

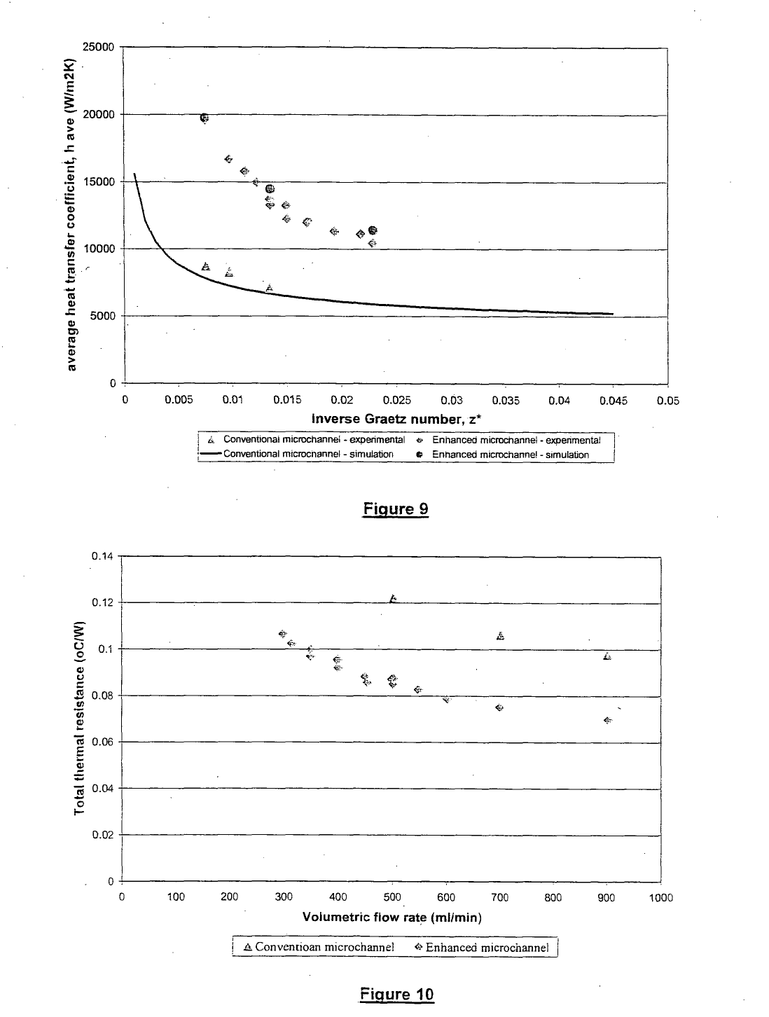

FIG. 9 shows the comparison of heat transfer performance between conventional microchannel and enhanced microchannel for experimental set #1. Results from simulation and experimental are both tabulated in the same graph. Experimental results on enhanced microchannel heat sink showed significant increment of average heat transfer coefficient against the conventional microchannel heat sink. A ˜80% heat transfer enhancement is demonstrated against the conventional configuration for the flow rates at ˜500 ml/min (Re˜450) while the percentage of enhancement increases to ˜150% when the flow rate is raised to ˜900 ml/min (Re˜850). It is also noted that the simulation results matched well with the experimental findings for both conventional microchannel and enhanced microchannel test pieces, showing that simulation is able to predict the heat transfer performance of conventional and enhanced microchannel with oblique cuts with good accuracy.

The significant heat transfer enhancement is also evident from the plots of total thermal resistance versus volumetric flow rate for both heat sinks. As noted in FIG. 10, total thermal resistance for both test pieces is reduced as the volumetric flow rate increases. The total thermal resistance of enhanced microchannel with oblique cuts is ˜30% lower in comparison with the conventional microchannel. In addition, the maximum pressure drop across the enhanced microchannel with oblique cuts recorded is merely ˜3 kPa when the flow rate is set at ˜900 ml/min.

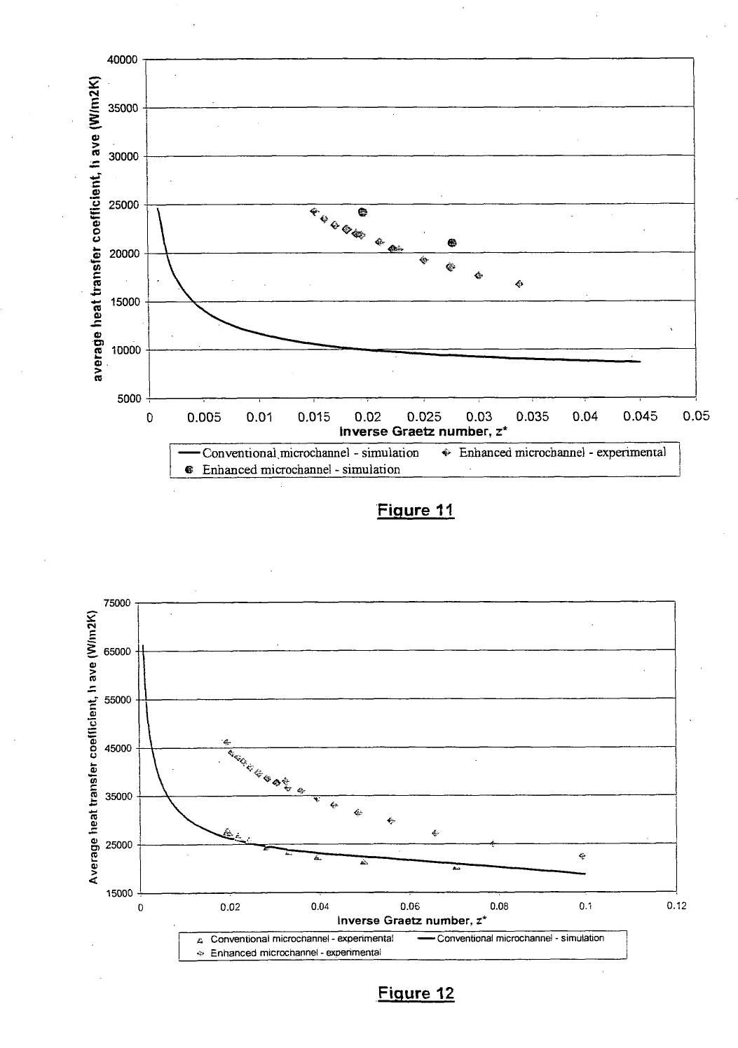

FIG. 11 shows the comparison of heat transfer performance between conventional microchannel and enhanced microchannel for experimental set #2. The predicted average heat transfer coefficient for conventional microchannel is plotted as baseline for performance comparison. Experimental results on enhanced microchannel showed that the increment in average heat transfer coefficient is at ˜80% against the conventional configuration for the flow rates at ˜400 ml/min (Re˜350) while the percentage of enhancement increases to ˜150% when the flow rate is raised to ˜900 ml/min (Re˜620). Again, the experimental results showed the heat transfer enhancement is significant. It is also noticeable that simulation is able to predict the heat transfer performance of enhanced microchannel with oblique cuts relatively well. In addition, the maximum pressure drop across the enhanced microchannel recorded is merely ˜5 kPa when the flow rate is set at ˜900 ml/min.

Heat transfer performance comparison between the silicon based conventional microchannel and enhanced microchannel (experimental set #3) is showed in FIG. 12. The predicted heat transfer coefficient for conventional microchannel is plotted as benchmark for performance comparison. Experimental data shows that enhanced microchannel achieved a ˜30% heat transfer enhancement at flow rate as low as ˜125 ml/min (Re˜180). When the flow rate is raised, percentage of heat transfer augmentation would increase significantly. At flow rate ˜500 ml/min (Re˜680), the heat transfer augmentation can be as high as 125% compared with conventional microchannel.

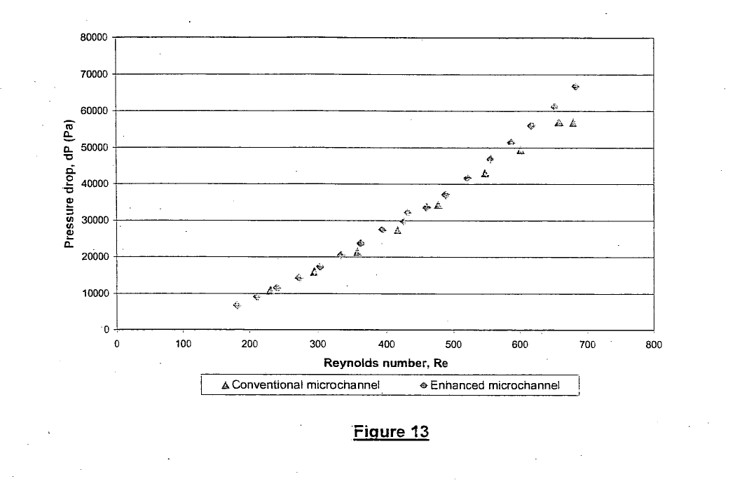

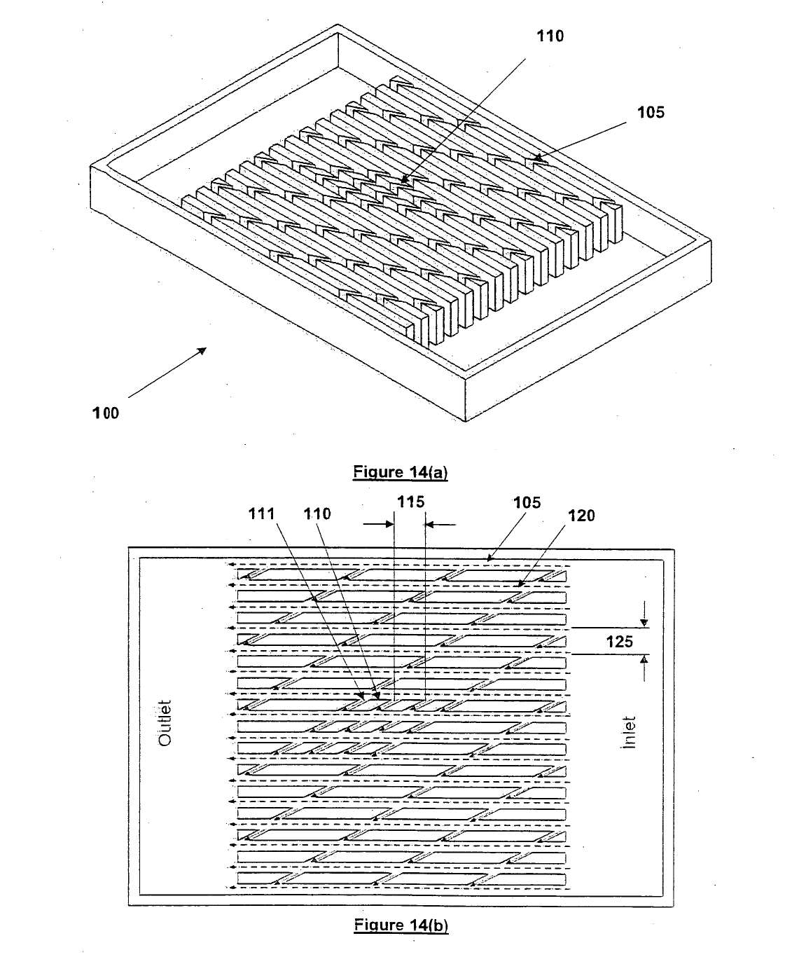

FIG. 13 displays the pressure drop for both test pieces, showing a comparable pressure drop between conventional microchannel and enhanced microchannel. Thus, the significant heat transfer enhancement can be achieved with no or little pressure drop penalty. Besides the uniform fin pitch configuration, the proposed scheme may also be applicable for non-uniform fin pitch configuration. For instance, the fin pitch 115 can be reduced at selected locations, such as a hotspot or heat concentration zones 110, to promote greater heat transfer. This feature is particularly attractive for hotspot mitigation. As shown in FIGS. 14(a) and (b), oblique channels 111 with finer pitch 115 are deployed at the center of the heat dissipation zone 105, where a hotspot 110 with higher heat flux dissipation is simulated.

It will be appreciated that in addition to, or instead of, varying the pitch, or spacing, of the oblique channels within the heat concentration zone, it may also be effective to vary the spacing of the transverse channel at this for this zone.

Thermal boundary layer redevelopment and flow diversion will occur at higher frequency at the region where finer pitch fins 112 are deployed as illustrated in the FIG. 14(a) & (b). Simulation is performed for this configuration to study the effectiveness of finer fin pitch in mitigating hotspot in electronics. Three different configurations of microchannel are simulated, namely the conventional, enhanced microchannel with uniform (larger) fin pitch and enhanced microchannel with non-uniform fin pitch. The detailed geometric parameters are listed in Table 4. The coolant, water in this case, flows through the silicon microchannels with a mean velocity of 1 m/s and Reynolds number of 160.

TABLE 4
Geometric parameters of the enhanced microchannel heat sink with non-uniform fin pitch.

| | | | | Fin length | Fin length | Fin pitch | Fin pitch | | | |
|---|---|---|---|---|---|---|---|---|---|---|
| Aspect | Fin | Channel | Channel | (larger | (smaller | (larger | (smaller | Substrate | Heat | Heat |
| ratio | width W_{w} | width W_{c} | height H | pitch) L₁ | pitch) L₂ | pitch) p₁ | pitch) p₂ | thickness t | flux q₁″ | flux q₂″ |
| α | (μm) | (μm) | (μm) | (μm) | (μm) | (μm) | (μm) | (μm) | (W/cm²) | (W/cm²) |
| 4 | 100 | 100 | 400 | 770 | 170 | 900 | 300 | 200 | 100 | 300 |

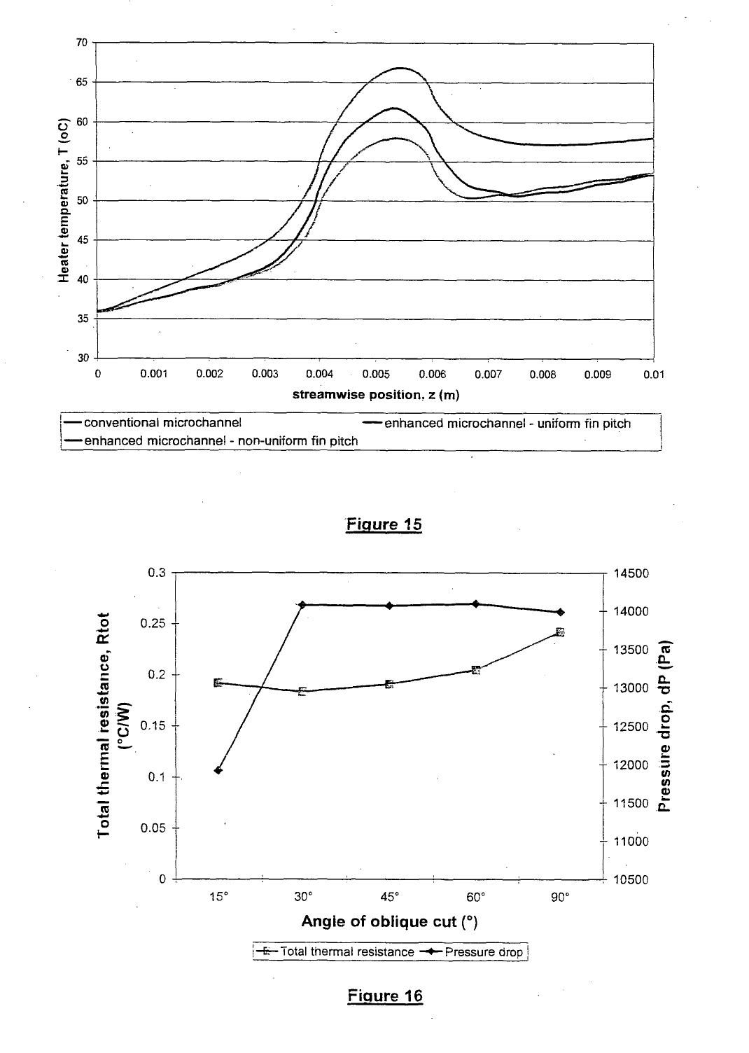

Bottom wall temperature profile for three different microchannel configurations simulated is plotted in FIG. 15. The conventional microchannel registered the highest bottom wall temperature among the three at 66.9° C. with the temperature gradient at 30.9° C. On the other hand, the enhanced microchannel heat sink with uniform fin pitch would reduce the maximum bottom wall temperature and its temperature gradient to 61.8° C. and 25.0° C. respectively. For the non-uniform fin pitch scheme where finer fins are deployed on top of the hotspot, further temperature reduction is noticed. Maximum bottom wall temperature is further reduced to 58.0° C. with its temperature gradient is reduced to 22.1° C. It is obvious that the proposed scheme can be very effective in mitigating hotspot issue of electronics.

In addition to the advantages presented by the oblique channels, there may be further benefit in presenting the oblique channels at particular angles.

FIG. 16 shows a characteristic whereby Total Thermal Resistance (Rtot) is plotted as a function of Oblique Angle. The Pressure Drop experienced again as a function of Oblique Angle is also provided. The maximum total thermal resistance, or lowest surface temperature, achieved when the oblique angle is set to 30°. Higher total thermal resistance with almost comparable pressure drop is observed when the oblique angle increases.

The configuration with oblique angle 15° generates the much lower pressure drop across the heat sink with slightly higher total thermal resistance as compared to the configuration 30° angle. However, this configuration may not be practical as an optimum configuration due to the very thin fins created from the steep cutting angle. This might compromise the structural integrity of the fins and might not be feasible for fabrication. Nevertheless, the performance at this angle still falls within the present invention, and is not rejected as a possible optimum performance merely because of fabrication issues.

Based on the characteristic of FIG. 16, an angle in the range 15° to 45° achieves a beneficial result, though performance up to 60° degrees may still yield an acceptable result subject to desired conditions.

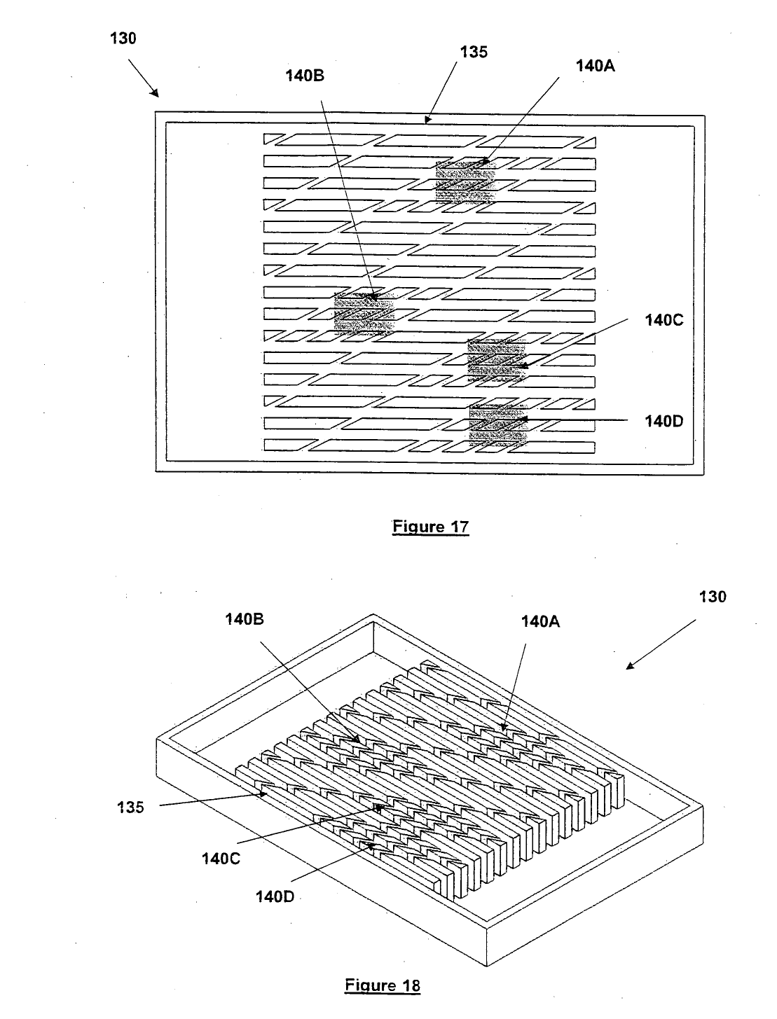

FIGS. 17 and 18 show a further embodiment of a heat sink device 130, whereby the heat dissipation zone 135 contains multiple heat concentration zones 140A to D. It will be appreciated that for specific applications, the present invention may be designed to have the beneficial heat dissipation effect overall the entire area, but certain hotspots may exist that require enhanced heat dissipation effect. The embodiment of FIGS. 17 and 18 show the capacity of the present invention to accommodate this requirement by providing multiple heat concentration zones, accurately positioned so as to coincide with the positioning of the electronic component, such as an integrated circuit.

The current technology, i.e. conventional microchannel, entails deteriorating heat transfer performance as the boundary layers continue to develop and thicken downstream. The proposed technology is a significant improvement as both local and average heat transfer performances can be significantly enhanced due to the re-initialization of boundary layers and the introduction of secondary flow. The proposed scheme may be more flexible where the dimensions of key parameters may be varied and non-uniform fin pitch configuration employed to tailor the local heat transfer performance. In addition, this passive heat transfer enhancement technique incurs little or no pressure drop penalty.

Compared with conventional microchannels, enhanced microchannels with oblique channels have much higher heat removal capacity. Such a high-efficiency cooling systems can be key enablers for the successful development of future generations of high power density electronic components and devices. This technology contributes directly and significantly to electronic cooling technologies employing microchannels, and it is useful and imperative for future electronic cooling applications.

We claim:

1. A heat sink device for dissipating heat from an electronic component mounted thereto, the device comprising
an inlet for receiving a fluid
an outlet for venting said fluid
a heat dissipation zone intermediate the inlet and outlet
said zone including a plurality of transverse channels and a plurality of oblique channels extending between adjacent transverse channels;
wherein said oblique and transverse channels define a fluid path for said fluid from the inlet to the outlet.

2. The heat sink device according to claim 1, wherein said oblique channels are positioned at an angle to the transverse channel in the range 15° to 45°.

3. The heat sink device according to claim 1, wherein said oblique channels are positioned at an angle to the transverse channel in the range 20° to 45°.

4. The heat sink device according to claim 1, wherein said oblique channels are positioned at an angle of 30° to the transverse channel.

5. The heat sink device according to claim 1, wherein the cross-sectional area of any one of the oblique channels is less than the cross-section area of the transverse channels between which the oblique channel extends.

6. The heat sink device according to claim 1, wherein elements of the heat dissipation zone separating the channels are heat dissipation fins, said fins in heat transfer communication with the electronic component.

7. The heat sink device according to claim 1, wherein the oblique channels are uniformly spaced from each other within the heat dissipation zone.

8. The heat sink device according to claim 1, further including at least one heat concentration zone within the heat dissipation zone, such that spacing of oblique channels within the at least one heat concentration zone is less than the spacing of the oblique channels within a remaining portion of the heat dissipation zone.

9. The heat sink device according to claim 1, further including at least one heat concentration zone within the heat dissipation zone, such that spacing of transverse channels within the at least one heat concentration zone is less than the spacing of the transverse channels within a remaining portion of the heat dissipation zone.

10. The heat sink device according to claim 8, wherein there is a plurality of heat concentration zones within the heat dissipation zone.

11. The heat sink device according to claim 1, wherein fluid flow within the transverse and/or oblique channels has a Reynold's Number less than 2300.

12. The heat sink device according to claim 9, wherein there is a plurality of heat concentration zones within the heat dissipation zone.
